(19) United States
(12) Patent Application Publication
(10) Pub. No.: US 2026/0082668 A1
(43) Pub. Date: Mar. 19, 2026

(54) GAP FILL APPROACH FOR HIGH ASPECT RATIO SHEET-SHEET SPACING ON NANO-SHEET STRUCTURE

(71) Applicant: Taiwan Semiconductor Manufacturing Co., Ltd., Hsinchu (TW)

(72) Inventors: Tsung-Han Shen, Taoyuan City (TW); Yu Tai Tsai, Taichung City (TW); Wei-Chin Lee, Taipei City (TW); Kuan-Ting Liu, Hsinchu (TW); Chi On Chui, Hsinchu (TW)

(21) Appl. No.: 18/889,057

(22) Filed: Sep. 18, 2024

(51) Int. Cl. H01L 29/49; H01L 21/8234; H01L 27/088; H01L 29/06; H01L 29/423; H01L 29/51; H01L 29/66; H01L 29/775; H01L 29/786

(52) U.S. Cl. CPC H10D 64/667; H10D 30/014; H10D 30/43; H10D 30/6735; H10D 30/6757; H10D 62/121; H10D 64/693; H10D 84/013; H10D 84/038; H10D 84/83

(57) ABSTRACT

A semiconductor device and method of forming is provided. The method includes forming a first work function metal layer around a first nanostructure in a fin disposed over a substrate, oxidizing at least a portion of the first work function metal layer, where less of the work function metal layer is oxidized between the first nanostructure and an adjacent second nanostructure in a stack in the fin, removing oxidized portions of the first work function metal layer from around the first nanostructure, and forming a second work function metal layer around the first nanostructure, where the first work function metal layer and the second work function metal layer fill a void between the first nanostructure and the adjacent second nanostructure.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2 through 4, 5A-B, 6A-B, 7A-C, 8A-B, 9A-B, 10A-D, 11A-D, 12A-B, 13A-B, 14A-B, 15A-B, 16A-B, 17A-B, 18A-B, 19A-C, 20A-C, and 21A-C illustrate varying views of intermediary steps of manufacturing a nano-FET transistor, in accordance with some embodiments;

FIG. 16C illustrates a detailed view of 16A before oxidizing a first work function metal layer, according to some embodiments;

FIG. 16D illustrates a detailed view of 16A after oxidizing the first work function metal layer, according to some embodiments;

FIG. 16E illustrates a detailed view showing potential alternative embodiments of the first work function metal layer after oxidation, according to some embodiments;

FIG. 17C illustrates a detailed view of FIG. 17A, according to some embodiments;

FIG. 17D illustrates a detailed view showing potential alternative embodiments of the first work function metal layer after removal of the surface oxide layer, according to some embodiments; and

FIGS. 18C and 18D illustrate detailed views of portions of the structures shown in FIGS. 18A and 18B, respectively, in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to semiconductor devices and methods for enhancing performance and reducing defects, particularly in the context of nanostructure field-effect transistors (nano-FETs). As the semiconductor industry strives to increase the integration density of electronic components, the challenge of managing and improving the performance of these densely packed structures becomes increasingly complex. This disclosure relates to techniques and structures that address these challenges by utilizing a Disposable Oxide Interposer (DOI) process.

In some embodiments, the disclosed semiconductor device includes a substrate with nanostructures formed thereon, where the nanostructures serve as channel regions for nano-FETs. The DOI process involves the use of an oxide material, such as silicon dioxide (SiO₂), silicon oxynitride (SiON), aluminum oxide (Al₂O₃), or the like, to replace silicon germanium (SiGe) as a dummy material during the manufacturing process. This substitution is advantageous as it reduces the intermixing of silicon and germanium and eases the diffusion of germanium through the oxide/silicon interface. As a result, the nanostructures retain a larger height and experience less metal gate extrusion, leading to improved device performance and reliability.

Additionally, in the DOI process, the nanostructures retain a more rectangular shape with smaller openings between nanostructures. The disclosed method further utilizes gradient oxidation and selective etching to make sheet-sheet opening profiles transfer from re-entrant to V-shape. Work function metal would become easier to fill in sheet-to-sheet spacing and seams between work function metal in inner sheet become less in a gate all around (GAA) structure.

The disclosed semiconductor device and method offer several advantages over conventional techniques. By reducing the diffusion of germanium and preventing NMG extrusion defects, the disclosed method enables the fabrication of nano-FETs with enhanced electrical characteristics, such as lower resistance and higher drive currents. Additionally, the larger channel height achieved through the DOI process contributes to a reduction in channel resistance, further enhancing the performance of the semiconductor device. Further, by using the DOI process with the improved work function metal formation techniques, punch-through during etching may be reduced, preventing fin-top damage and also providing for full coverage of the metal-cap film.

In summary, the disclosed semiconductor device and method represent a substantial advancement in the field of nano-FET fabrication. By addressing the technical problems associated with Si/Ge intermixing and metal gate extrusion, the disclosed techniques provide a pathway to manufacturing semiconductor devices with superior performance and reduced defects.

Embodiments are described below in a particular context, a die comprising nano-FETs. Various embodiments may be applied, however, to dies comprising other types of transistors (e.g., stacking transistors, or the like) in lieu of or in combination with the nano-FETs.

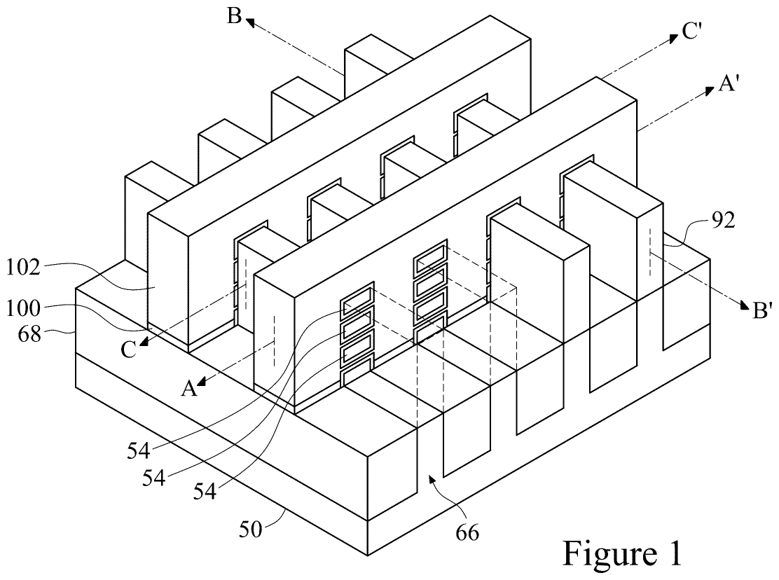

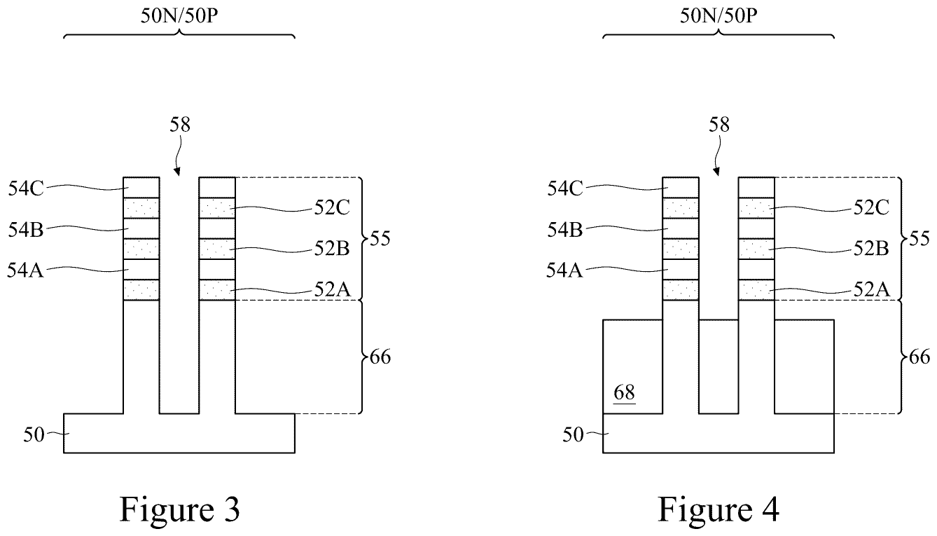

FIG. 1 illustrates an example of nano-FETs (e.g., nanowire FETs, nanosheet FETs (Nano-FETs), or the like) in a three-dimensional view, in accordance with some embodiments. Certain features are simplified and/or omitted in FIG. 1 for ease of illustration. The nano-FETs comprise second nanostructures 54 (e.g., nanosheets, nanowire, or the like) over fins 66 on a substrate 50 (e.g., a semiconductor substrate), wherein the second nanostructures 54 act as channel regions for the nano-FETs (as will be described in further detail below, first nanostructures 52 (see FIG. 3) are also formed, but first nanostructures 52 are removed in an intermediate process step in the formation of the nana-FETs illustrated in FIG. 1). The second nanostructure 54 may include p-type nanostructures, n-type nanostructures, or a combination thereof. Shallow trench isolation (STI) regions 68 (also referred to as STI structures or STI regions) are disposed between adjacent fins 66, which may protrude above and from between neighboring STI regions 68. Although the STI regions 68 is described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portions extending between the neighboring STI regions 68.

Gate dielectric layers 100 are over top surfaces of the fins 66 and along top surfaces, sidewalls, and bottom surfaces of the second nanostructures 54. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

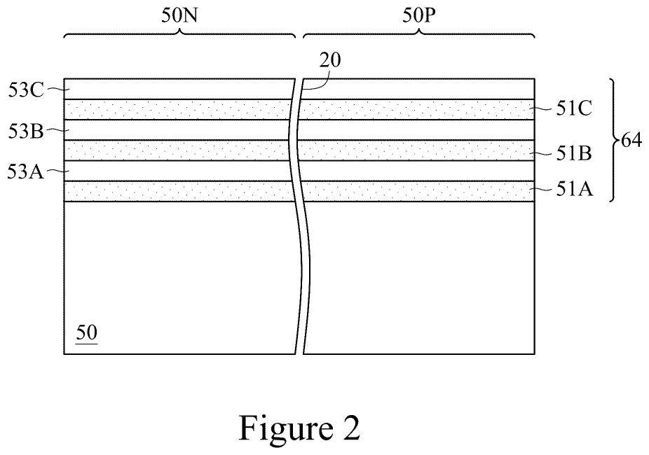

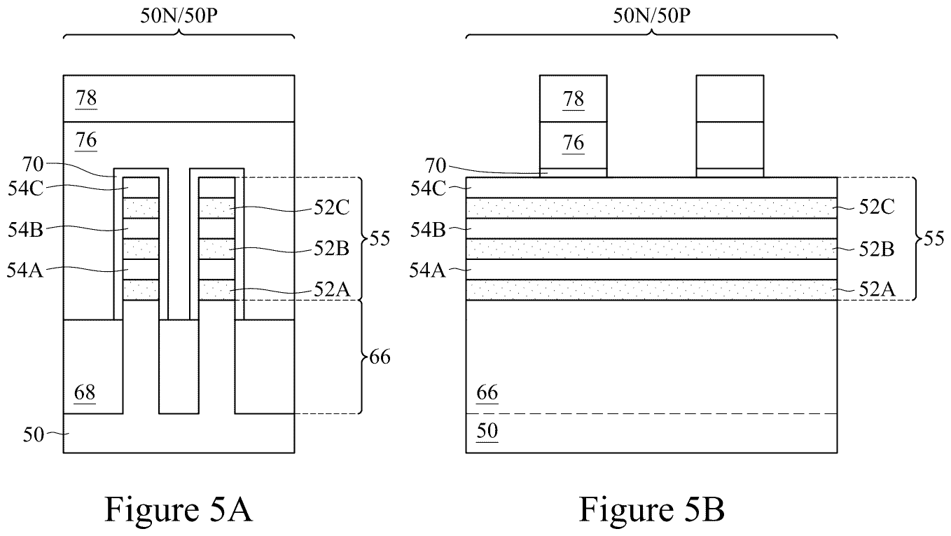

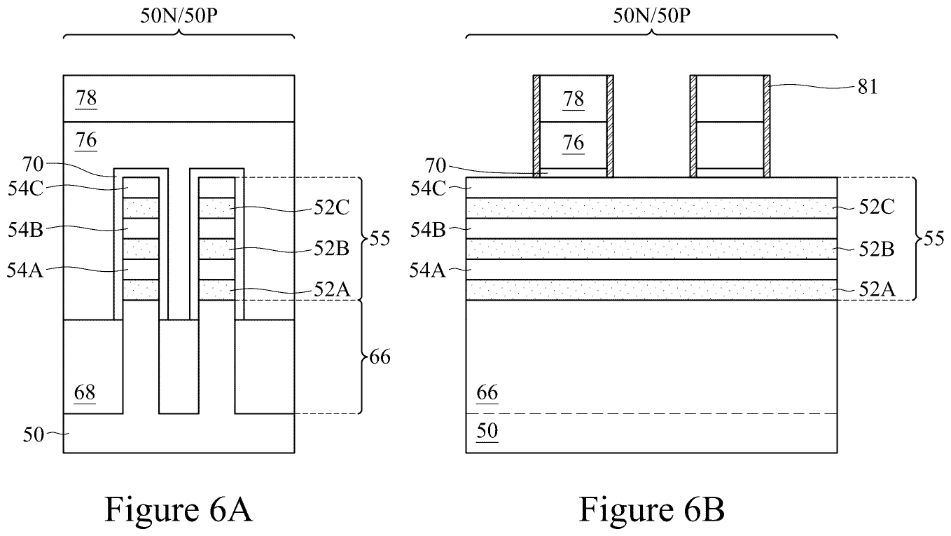

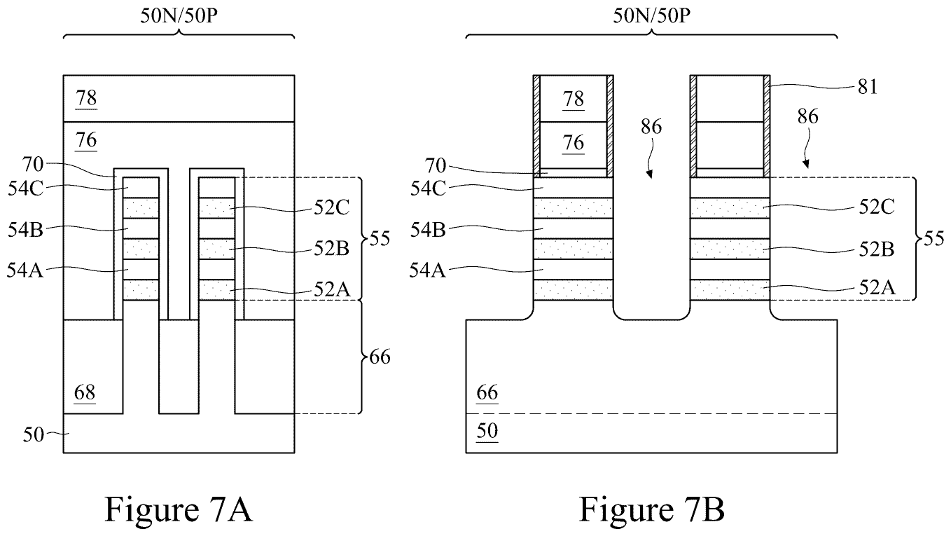

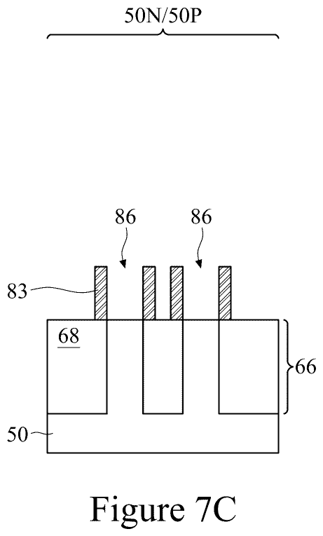

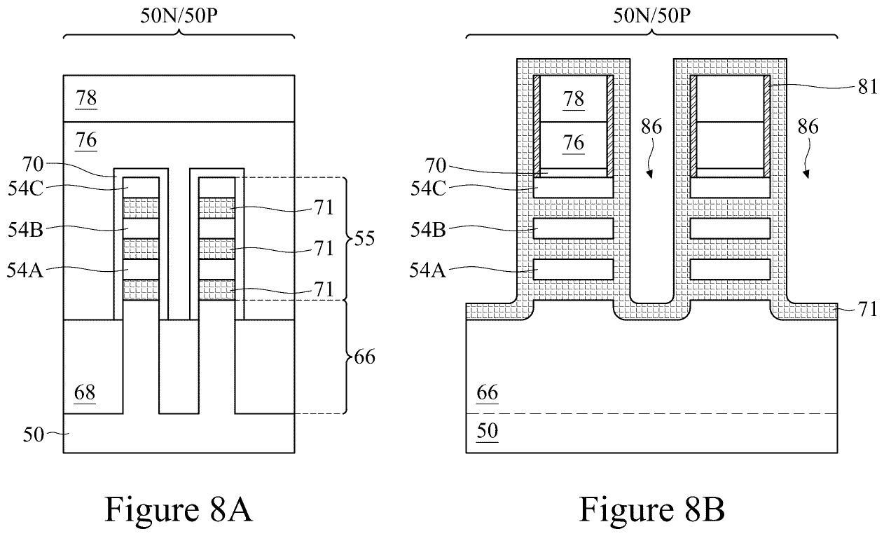

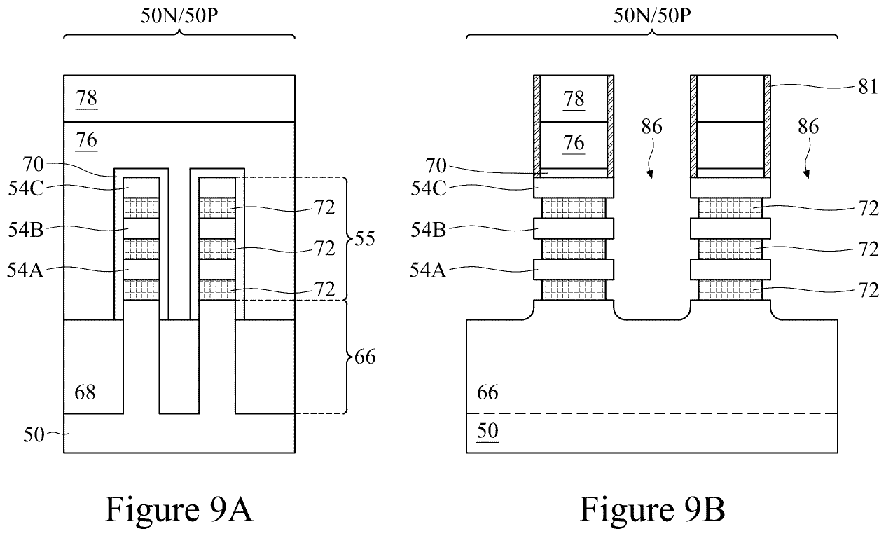

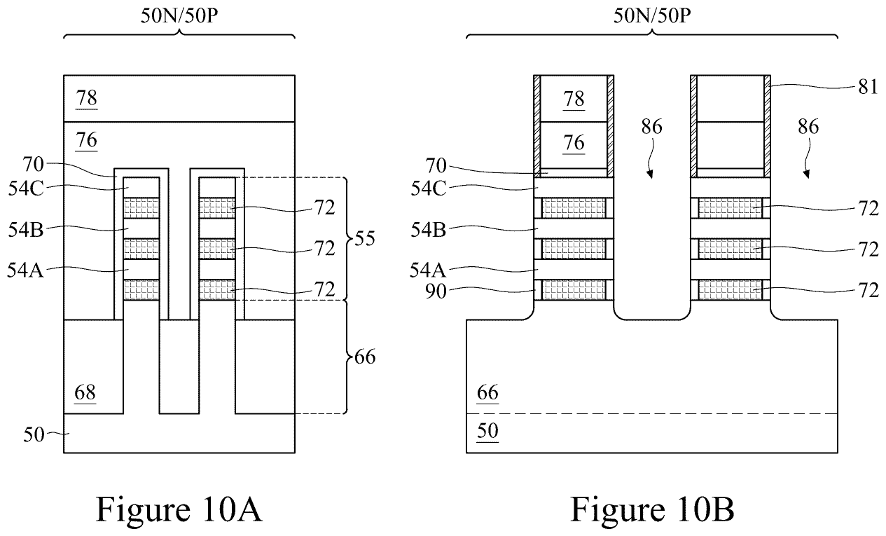

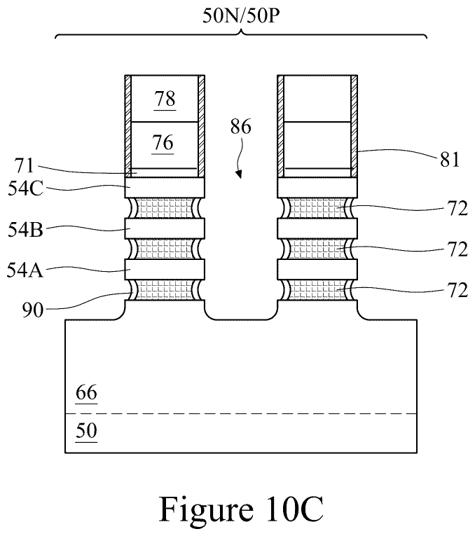

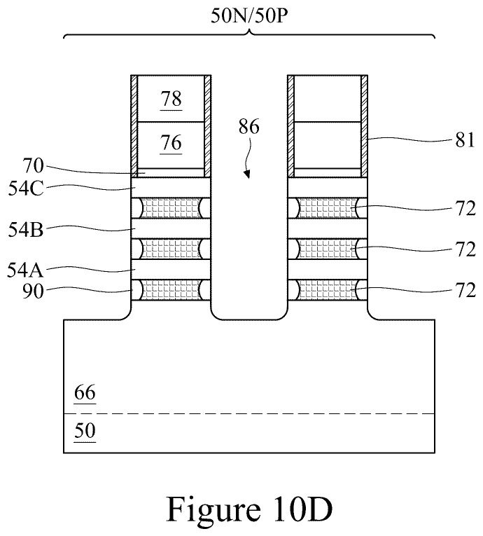

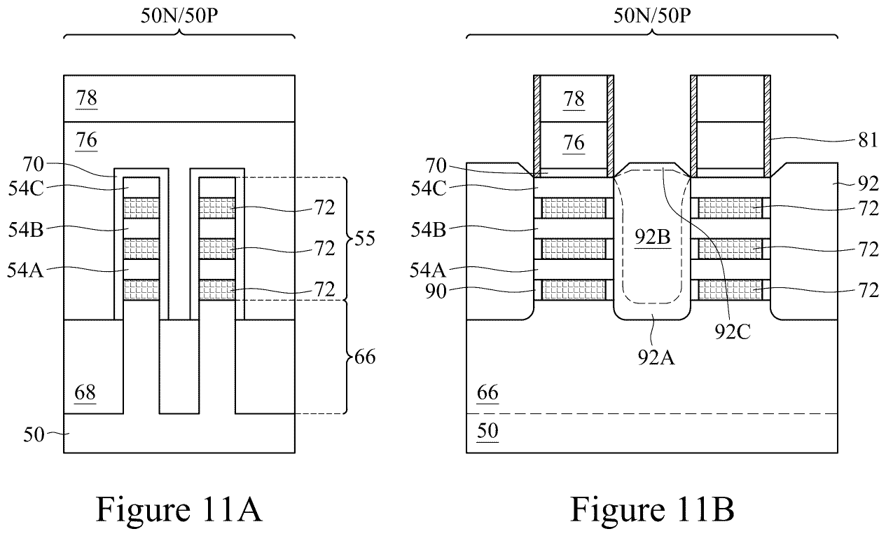

FIGS. 2 through 4, 5A, 5B, 6A, 6B, 7A, 7B, 7C, 8A, 8B, 9A, 9B, 10A, 10B, 10C, 10D, 11A, 11B, 11C, 11D, 12A, 12B, 13A, 13B, 14A, 14B, 15A. 15B, 16A, 16B, 17A, 17B, 18A, 18B, 19A, 19B, 19C, 20A, 20B, 20C, 21A, 21B, and 21C are cross-sectional views of intermediate stages in the manufacturing of nano-FETs, in accordance with some embodiments. FIGS. 2-4, 5A, 6A, 7A, 8A, 9A, 10A. 11A, 12A, 13A, 14A, 15A, 16A, 17A, 19A, 20A, and 21A illustrate reference cross-section A-A′ illustrated in FIG. 1. FIGS. 5B, 6B, 7B, 8B, 9B, 10B, 10C, 10D, 11B, 12B, 13B, 14B, 15B, 16B, 17B, 18B, 19B, 20B, and 21B illustrate reference cross-section B-B′ illustrated in FIG. 1. FIGS. 7C, 11C, 11D, 19C, 20C, and 21C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type region 50N and p-type region 50P may be provided. Subsequent figures describe processing steps that may be performed in either the n-type region 50N or the p-type region 50P unless otherwise noted.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 will be removed and the second semiconductor layers 53 will be patterned to form channel regions of nano-FETs in both the n-type region 50N and the p-type region 50P. Nevertheless, in some embodiments, the second semiconductor layers 53 may be removed and the first semiconductor layers 51 may be patterned to form channel regions of nano-FETs in both the n-type region 50N and the p-type region 50P. For example, the channel regions in both the n-type region 50N and the p-type region 50P may have a same material composition (e.g., silicon, or another semiconductor material) and be formed simultaneously.

In other embodiments, the first semiconductor layers 51 may be removed and the second semiconductor layers 53 may be patterned to form channel regions of nano-FETs in the p-type region 50P, and the second semiconductor layers 53 may be removed and the first semiconductor layers 51 may be patterned to form channel regions of nano-FETs in the n-type region 50N. In still other embodiments, the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In such embodiments, the channel regions of the n-type region 50N may have a different material composition than the channel regions of the p-type region 50P. The first semiconductor layers 51 and the second semiconductor layers 53 may be selectively removed from each of the n-type region 50N and p-type region 50P through additional masking and etching steps. For example, the channel regions of the n-type region 50N may be silicon channel regions while the channel regions of the p-type region 50P may be silicon germanium channel regions.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

In various embodiments, the first semiconductor layers 51 may be formed of a first semiconductor material, such as silicon germanium, or the like, and the second semiconductor layers 53 may be formed of a second semiconductor material, such as silicon, silicon carbon, or the like. The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions of the nano-FETs.

Referring now to FIG. 3, fins 66 are formed in the substrate 50 and nanostructures 55 are formed in the multi-layer stack 64 (shown in FIG. 2), in accordance with some embodiments. In some embodiments, the nanostructures 55 and the fins 66 may be formed in the multi-layer stack 64 (shown in FIG. 2) and the substrate 50, respectively, by etching trenches 58 in the multi-layer stack 64 (shown in FIG. 2) and the substrate 50. The etching may be any acceptable etch process, such as a reactive ion etch (RIE), neutral beam etch (NBE), the like, or a combination thereof. The etching may be anisotropic. During the etching process, a hard mask (not illustrated) may be used to define a pattern of the fins 66 and the nanostructures 55. The hard mask may comprise any suitable insulating material, such as an oxide, a nitride, and oxynitride, and oxycarbonitride, or the like. In some embodiments (not separately illustrated), the hard mask may be a multi-layer structure. The hard mask may be formed over the nanostructures 55 using an acceptable process(es) such as thermal oxidation, physical vapor deposition (PVD), CVD, ALD, combinations thereof, or the like.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, a sacrificial layer may be formed over a substrate and patterned using a photolithography process. Spacers may then be formed alongside the patterned sacrificial layer using a self-aligned process. The sacrificial layer is then removed, and the remaining spacers may then be used to pattern the fins 66 and the nanostructures 55.

Forming the nanostructures 55 by etching the multi-layer stack 64 (shown in FIG. 2) may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as the nanostructures 55.

FIG. 3 illustrates the fins 66 having substantially equal widths for illustrative purposes. In some embodiments, widths of the fins 66 in the n-type region 50N may be greater or thinner than the fins 66 in the p-type region 50P, or vice versa. Further, while FIG. 3 illustrates each of the fins 66 and the nanostructures 55 as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66 to fill the trenches 58. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

Further in FIG. 4, appropriate wells (not separately illustrated) may be formed in the fins 66 and/or the nanostructures 55. In embodiments with different well types, different implant steps for the n-type region 50N and the p-type region 50P may be achieved using a photoresist or other masks (not separately illustrated). For example, a photoresist may be formed over the fins 66 and the nanostructures 55 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66 and the nanostructures 55 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In FIGS. 5A and 5B, dummy gates 76 are formed over and along sidewalls of the nanostructures 55 and the fin 66. To form the dummy gates 76, first, a dummy dielectric layer is formed on the fins 66 and/or the nanostructures 55. The dummy dielectric layer may be silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. The mask layer may include, for example, silicon nitride, silicon oxynitride, or the like.

Subsequently, the mask layer may be patterned using acceptable photolithography and etching techniques to form masks 78. The pattern of the masks 78 then may be transferred to the dummy gate layer and to the dummy dielectric layer to form dummy gates 76 and dummy gate dielectrics 70, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66. It is noted that the dummy gate dielectrics 70 is shown covering only the fins 66 and the nanostructures 55 for illustrative purposes only. In some embodiments, the dummy gate dielectrics 70 may be deposited such that the dummy gate dielectrics 70 covers the STI regions 68, such that the dummy gate dielectrics 70 extends between the dummy gates 76 and the STI regions 68.

In FIGS. 6A and 6B, gate spacers 81 are formed over the nanostructures 55 and the STI regions 68, on exposed sidewalls of the masks 78 (if present), the dummy gates 76, and the dummy gate dielectrics 70. The gate spacers 81 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 76 (thus forming the gate spacers 81). As subsequently described in greater detail, the dielectric material(s), when etched, may also have portions left on the sidewalls of the semiconductor fins 66 and/or the nanostructures 55 (thus forming fin spacers 83, see FIG. 7C). After etching, the fin spacers 83 and/or the gate spacers 81 can have straight sidewalls (as illustrated) or can have curved sidewalls (not separately illustrated).

Further, implants for lightly doped source/drain (LDD) regions (not separately illustrated) may be performed. The LDD implants may be performed before the gate spacers 81 are formed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the semiconductor fins 66 and the nanostructures 55 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the semiconductor fins 66 and the nanostructures 55 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 10¹⁵ atoms/cm³ to about 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

In FIGS. 7A-7C, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 7C, top surfaces of the STI regions 68 may level with bottom surfaces of the first recesses 86. In other embodiments, the fins 66 may be etched such that bottom surfaces of the first recesses 86 are disposed above or below the top surfaces of the STI regions 68. The first recesses 86 may be formed by etching the fins 66, the nanostructures 55, and the substrate 50 using anisotropic etching processes, such as RIE, NBE, or the like. The gate spacers 81, the fin spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

In FIGS. 8A-9B, the first nanostructures 52 are replaced with sacrificial material segments 72 (also referred to as disposable oxide interposers (DOI) 72). Replacing the first nanostructures 52 may include etching away the first nanostructures 52 using a suitable etch process, such as an isotropic etch process, that is performed through the first recesses 86 as illustrated by FIGS. 8A-8B. The etch process may be selective to the material of the first nanostructures 52 and remove the first nanostructures 52 without significantly removing the second nanostructures 54 or the semiconductor fins 66. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to remove the first nanostructures 52.

Subsequently, a sacrificial material layer 71 is deposited in the first recesses 86 and spaces where the first nanostructures 52 were removed. The sacrificial material layer 71 may be deposited by a conformal deposition process, such as CVD, ALD, or the like. The sacrificial material layer may comprise an insulating material such as silicon oxide (e.g., SiO₂), silicon oxynitride (SiON), aluminum oxide (Al₂O₃), or the like that can be selectively etched from the second nanostructures 54. In FIGS. 9A-9B, the sacrificial material layer 71 may then be etched to form the sacrificial material segments 72. The etching may be isotropic or anisotropic. For example, the sacrificial material layer may be etched by a wet etch process using diluted HF, or the like as an etchant. In some embodiments, the etching is performed until sidewalls of the sacrificial material segments 72 are recessed past sidewalls of the second nanostructures 54. Although sidewalls of sacrificial material segments 72 are illustrated as being straight in FIG. 9B, the sidewalls may be concave or convex (see e.g., FIG. 10C).

Replacing the first nanostructures 52 with the sacrificial material segments 72 may provide advantages. For example, in subsequent source/drain formation steps, one or more high temperature processes may be performed to, for example, activate the dopants in the source/drain regions. When the material of the first nanostructures 52 (e.g., SiGe) is exposed to high temperatures, germanium intermixing and increased roughness at an interface between the first nanostructures 52 and second nanostructures 54 may result. Such manufacturing defects may degrade the performance of the resulting transistor devices. For example, when germanium diffuses into the second nanostructures 74, germanium residue may remain in channel regions of the resulting transistor devices, which negatively affects the performance of the channel regions. By replacing the first nanostructures 52 with an insulating material prior to the high temperature processes (e.g., source/drain annealing), manufacturing defects can be reduced and device performance can be improved (e.g., increased current drive, reduced capacitance, and improved short channel effect).

In FIGS. 10A and 10B, inner spacers 90 are formed in the first recesses 86 on the sidewalls of the sacrificial material segments 72. The inner spacers 90 act as isolation features between subsequently formed source/drain regions and a gate structure. As will be discussed in greater detail below, source/drain regions will be formed in the first recesses 86, while the sacrificial material segments 72 will be replaced with corresponding gate structures. The inner spacers 90 may also be used to prevent damage to subsequently formed source/drain regions by subsequent etching processes, such as etching processes used to form gate structures.

The inner spacers 90 may be formed by depositing an inner spacer layer (not separately illustrated) over the structures illustrated in FIGS. 9A and 9B. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 90. The inner spacer layer may be etched by an anisotropic etching process, such as RIE, NBE, or the like.

Although outer sidewalls of the inner spacers 90 are illustrated as being flush with sidewalls of the second nanostructures 54, the outer sidewalls of the inner spacers 90 may extend beyond or be recessed from sidewalls of the second nanostructures 54 (see e.g., FIG. 10C). Moreover, although the outer sidewalls of the inner spacers 90 are illustrated as being straight in FIG. 10B, the outer sidewalls of the inner spacers 90 may be concave or convex. FIG. 10C illustrates an embodiment in which sidewalls of the sacrificial material segments 72 are concave, outer sidewalls of the inner spacers 90 are concave, and the inner spacers 90 are recessed from sidewalls of the second nanostructures 54. Other configurations are also possible. For example, FIG. 10D illustrates an embodiment in which sidewalls of the sacrificial material segments 72 are concave, outer sidewalls of the inner spacers 90 are straight, and the inner spacers 90 are flush with sidewalls of the second nanostructures 54.

In FIGS. 11A-11D, epitaxial source/drain regions 92 are formed in the first recesses 86. In some embodiments, the source/drain regions 92 may exert stress on the second nanostructures 54 in the n-type region 50N and/or on the first nanostructures 52 in the p-type region 50P, thereby improving performance. As illustrated in FIG. 11B, the epitaxial source/drain regions 92 are formed in the first recesses 86 such that each dummy gate 76 is disposed between respective neighboring pairs of the epitaxial source/drain regions 92. In some embodiments, the gate spacers 81 are used to separate the epitaxial source/drain regions 92 from the dummy gates 76 and the inner spacers 90 are used to separate the epitaxial source/drain regions 92 from the sacrificial material segments 72 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 in the n-type region 50N may include materials exerting a tensile strain on the second nanostructures 54, such as silicon, silicon carbide, phosphorous doped silicon carbide, silicon phosphide, or the like.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 in the p-type region 50P may include materials exerting a compressive strain on the second nanostructures 54, such as silicon-germanium, boron doped silicon-germanium, germanium, germanium tin, or the like.

The epitaxial source/drain regions 92, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 11C. In other embodiments, adjacent epitaxial source/drain regions 92 remain separated after the epitaxy process is completed as illustrated by FIG. 11D. In the embodiments illustrated in FIGS. 11C and 11D, the fin spacers 83 may be formed on top surfaces of the STI regions 68, thereby blocking the epitaxial growth. In some other embodiments, the fin spacers 83 may cover portions of the sidewalls of the nanostructures 55 further blocking the epitaxial growth. In some other embodiments, the fin spacers 83 may be omitted, and the epitaxially grown region may extend to the surface of the STI regions 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

In FIGS. 12A and 12B, a first interlayer dielectric (ILD) 96 is deposited over the structure illustrated in FIGS. 11A and 11B, respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the gate spacers 81. The CESL 94 may comprise a dielectric material, such as, silicon nitride, silicon oxide, silicon oxynitride, or the like, having a different etch rate than the material of the overlying first ILD 96.

After the first ILD 96 is deposited, a planarization process, such as a CMP, may be performed to level the top surface of the first ILD 96 with the top surfaces of the dummy gates 76 (as shown) or the masks 78. The planarization process may also remove the masks 78 on the dummy gates 76, and portions of the gate spacers 81 along sidewalls of the masks 78. After the planarization process, top surfaces of the dummy gates 76, the gate spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the gate spacers 81.

In FIGS. 13A and 13B, the dummy gates 76, and the masks 78 if present, are removed in one or more etching steps, so that second recesses 98 are formed. Portions of the dummy gate dielectrics 70 in the second recesses 98 may also be removed. In some embodiments, the dummy gates 76 and the dummy gate dielectrics 70 are removed by an anisotropic dry etch process. For example, the etching process may include a dry etch process using reaction gas(es) that selectively etch the dummy gates 76 at a faster rate than the first ILD 96 or the gate spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 70 may be used as etch stop layers when the dummy gates 76 are etched. The dummy gate dielectrics 70 may then be removed after the removal of the dummy gates 76.

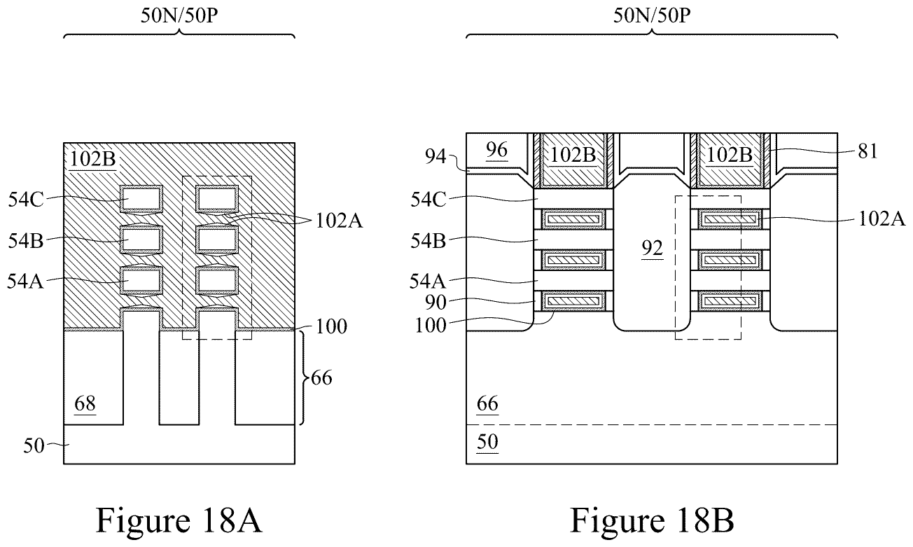

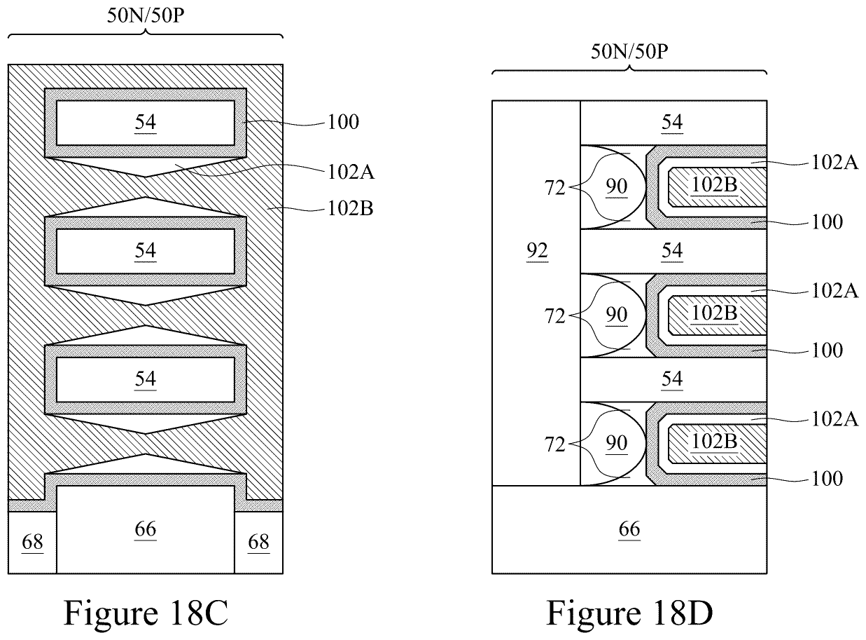

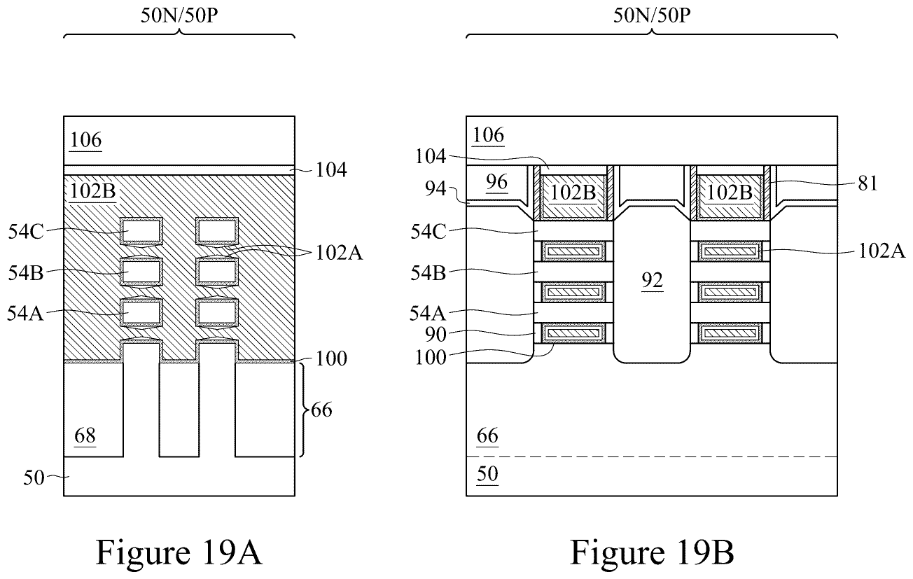

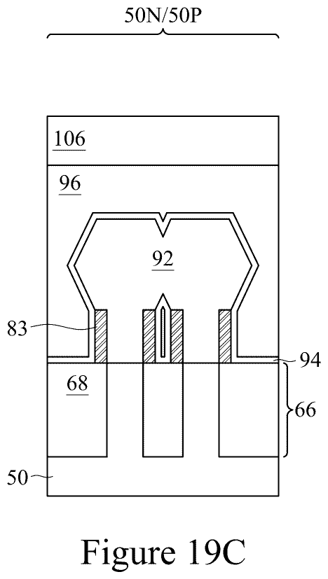

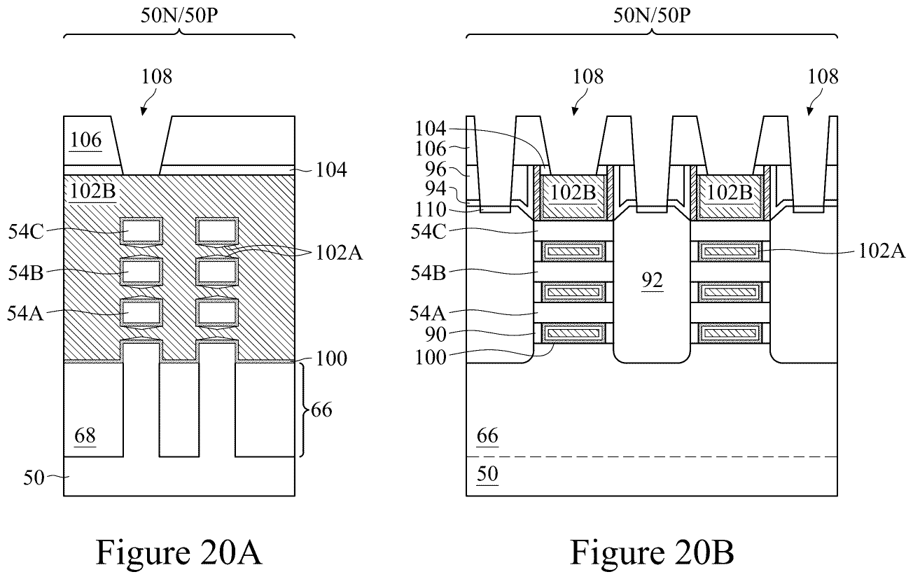

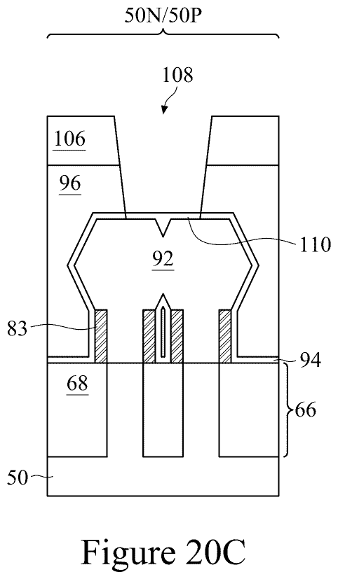

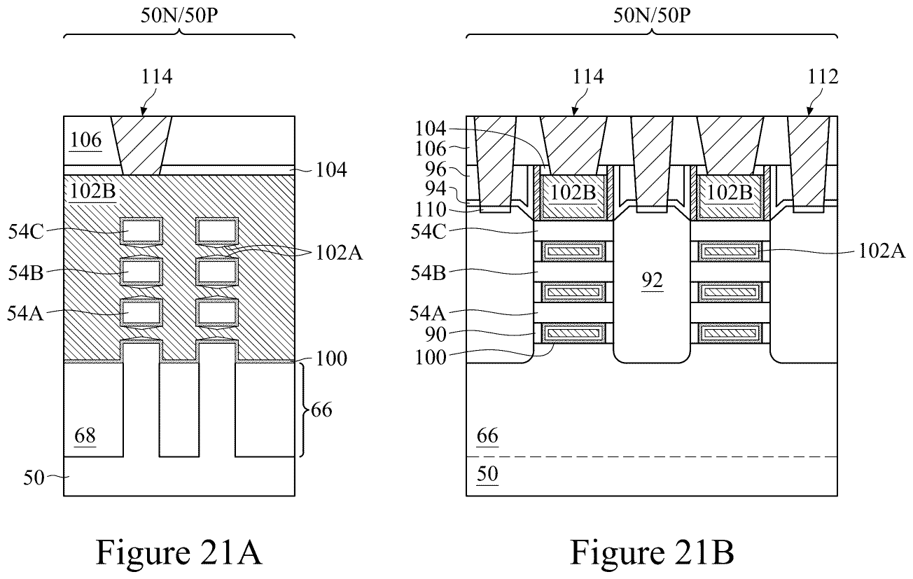

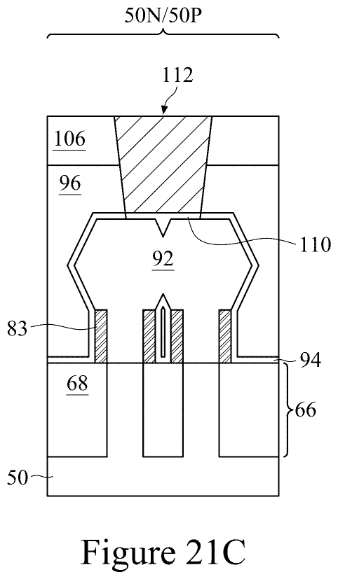

In FIGS. 14A and 14B, the sacrificial material segments 72 are removed, extending the second recesses 98. Removing the sacrificial material segments 72 may include performing an isotropic etching process such as wet etching or the like using etchants which are selective to the materials of the sacrificial material segments 72, while the second nanostructures 54 remain relatively unetched as compared to the sacrificial material segments 72. The sacrificial material segments 72 may be completely removed, or a residue of the sacrificial material segments 72 may remain on sidewalls of the inner spacers in the second recesses 98 (see e.g., FIG. 18D).

In some embodiments, the STI regions 68 may be etched while removing the sacrificial material segments 72, but the total amount of loss in the STI regions 68 may be reduced by controlling etching parameters (e.g., timing) while removing the sacrificial material segments 72. In other embodiments, the STI regions 68 may include a hard mask (not separately illustrated) at a top surface to protect the underlying STI regions 68 from etching while patterning and removing the sacrificial material segments 72. In such embodiments, the hard mask may comprise, for example, a nitride.

In FIGS. 15A-15B, gate dielectric layers 100 are formed, according to some embodiments. The gate dielectric layers 100 are deposited conformally in the second recesses 98. The gate dielectric layers 100 may be formed on top surfaces and sidewalls of the substrate 50 and on top surfaces, sidewalls, and bottom surfaces of the second nanostructures 54. In some embodiments, the gate dielectric layers 100 may also be deposited on top surfaces of the first ILD 96, the CESL 94, the gate spacers 81, and the STI regions 68. In such embodiments, the excess gate dielectric layers on the top surfaces of the first ILD 96, the CESL 94, the gate spacers 81 may be removed through a planarization process either before or after formation of the gate electrodes 102 (discussed below).

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The formation of the gate dielectric layers 100 in the n-type region 50N and the p-type region 50P may occur simultaneously such that the gate dielectric layers 100 in each region are formed from the same materials. In some embodiments, the gate dielectric layers 100 in each region may be formed by distinct processes, such that the gate dielectric layers 100 may be different materials and/or have a different number of layers. Various masking steps may be used to mask and expose appropriate regions when using distinct processes. In some embodiments, the height of the void between second nanostructures (sometimes referred to as the spacing between second nanostructures (Sₙ)) is from 5 to 10 nm.

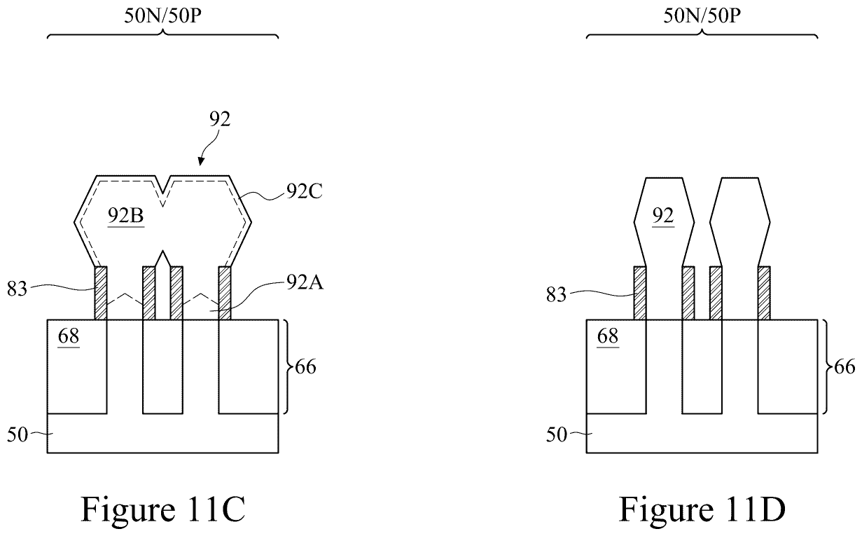

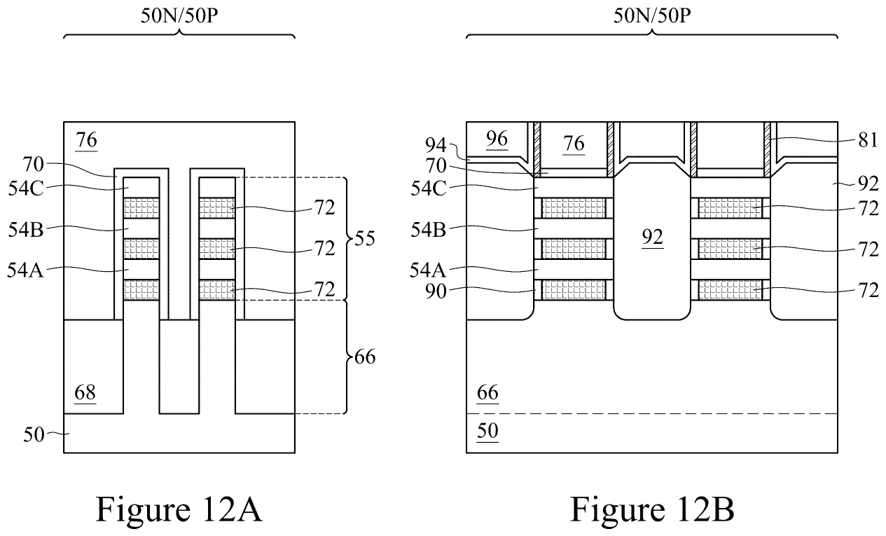

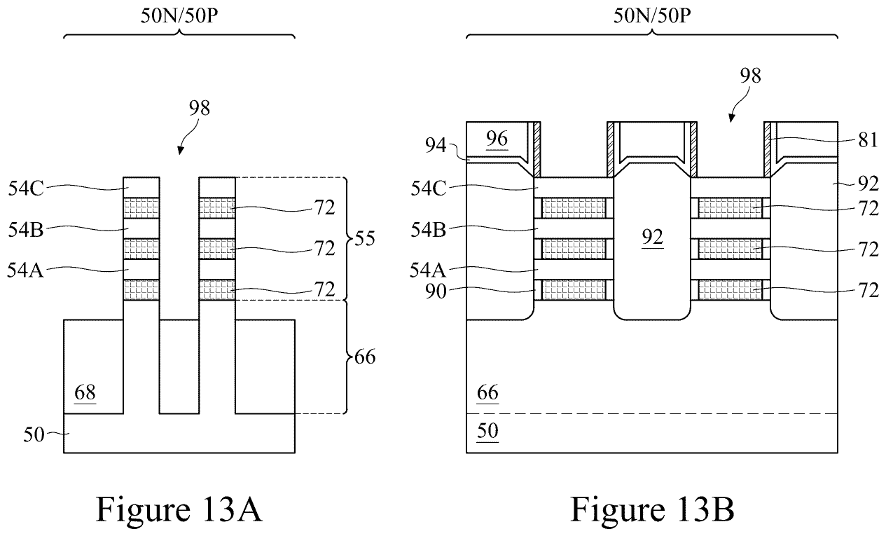

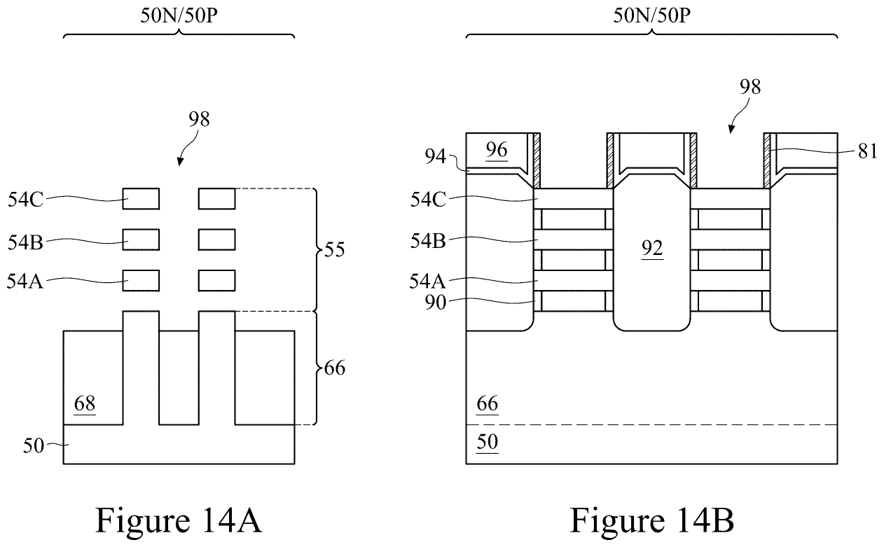

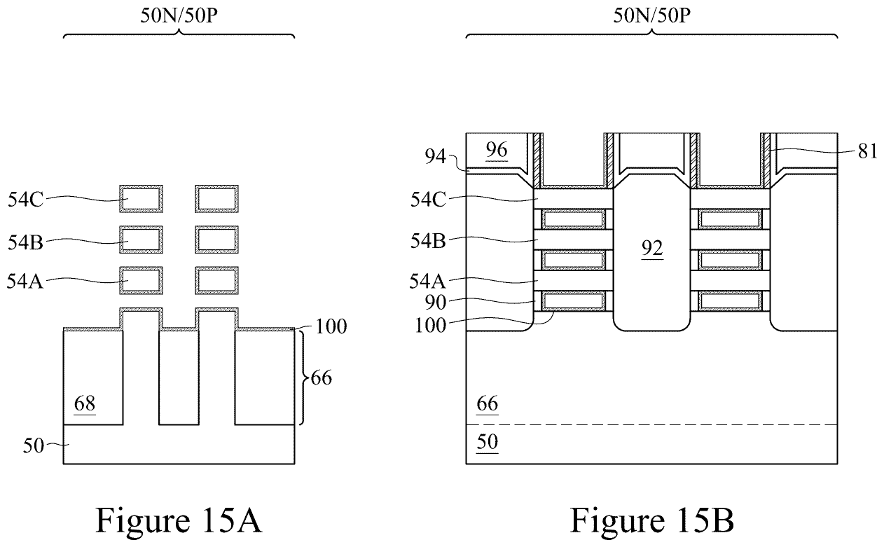

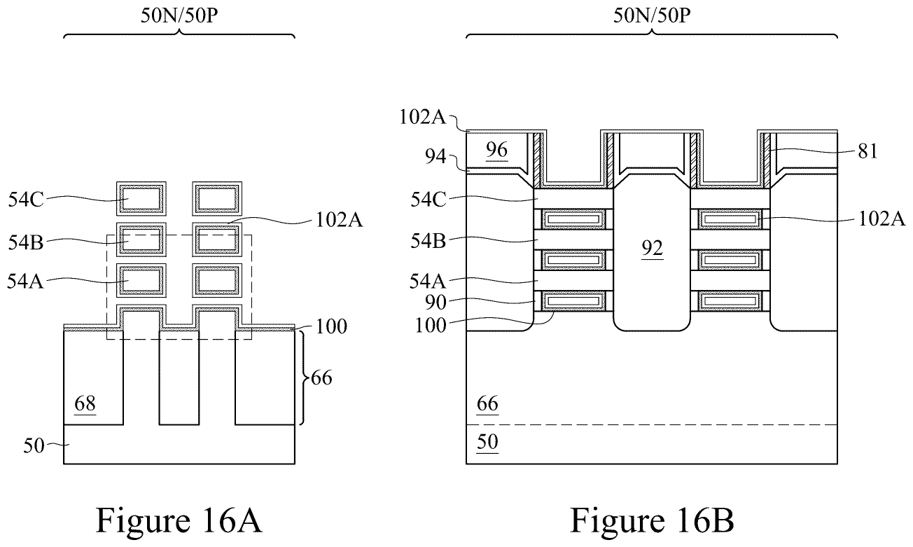

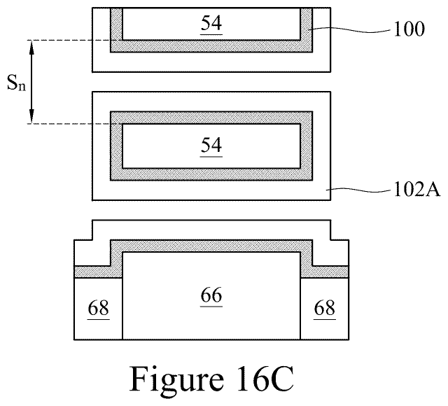

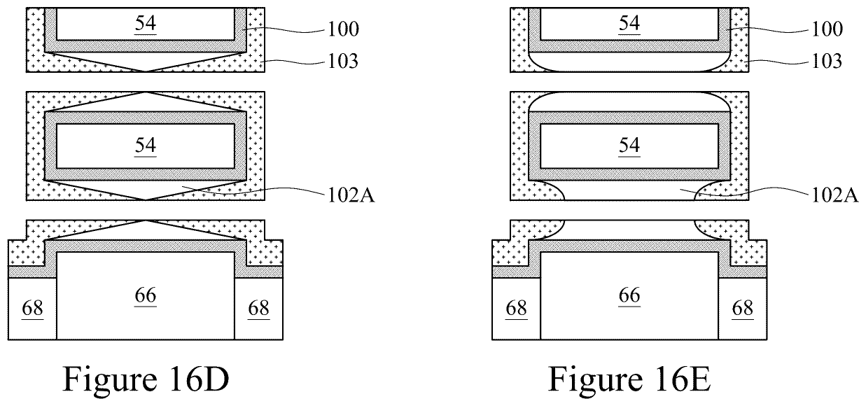

In FIGS. 16A-18B, multi-layered gate electrodes 102 are formed, according to some embodiments.

FIGS. 16A and 16B illustrate the deposition of a gate electrode first work function metal layer 102A, according to some embodiments. The first work function metal layer 102A is deposited over the gate dielectric layers 100 and exposed tops of the first ILD 96, gate spacers 81, and CESL 94. The first work function metal layer 102A may include a metal-containing material such as titanium nitride, titanium silicium nitride (TiSiN), titanium aluminum nitride (TiAlN), tungsten carbonitride (WCN), molybdenum nitride (MoN), aluminum-doped titanium carbide (TiAlC), or other work function metals having an oxidized form that exhibits a high etch selectivity in relation to the un-oxidized for and/or the gate dielectric layers 100 and second nanostructures 54 (or first nanostructures 52 in embodiments in which the second nanostructures 54 are the ones removed). The first work function metal layer 102A may be deposited by ALD, CVD, PVD, or the like. In some embodiments, the first work function metal layer 102A may be between 1 and 3.5 nm thick.

The first work function metal layer 102A may comprise a p-type work function metal (PWFM) or n-type work function metal (NWFM) to tune a work function of a device to a desired amount given the application of the device to be formed, and may be deposited using any acceptable deposition process. A mask layer may be patterned over substrate 50 to prevent deposition of the first work function metal layer 102A in particular regions. For example, where the first work function metal layer 102A is a PWFM, the mask layer may be formed and pattered to cover n-type region 50N to prevent deposition of the PWFM first work function metal layer 102A in n-type region 50N. The mask layer may be formed and patterned using any acceptable methods. In some embodiments, the mask layer may be the same mask used in relation to forming the gate dielectric layers 100, as discussed above. FIG. 16C illustrates an enlarged portion of boxed in portion of FIG. 16A to better illustrate the initial application of first work function metal layer 102A.

As shown in FIG. 16D, the first work function metal layer 102A may then be subjected to a gradient thermal oxidation procedure, according to some embodiments, transitioning a portion of the first work function metal layer 102A to a surface oxide layer 103. For example, where the first work function metal layer 102A is titanium nitride (TiN), the oxidation process results in formation of a surface oxide layer 103 of titanium oxide (TiO₂) while nitrogen is released as a byproduct. The oxidation process is generally an outside-to-inside process, where surface layers of the first work function metal layer 102A oxidize first when exposed to an oxygen rich atmosphere, resulting in an outer surface oxide layer 103 of oxidized metal transitioning in a gradient to the original deposited work function metal closer to the inner surface of the first work function metal layer 102A and the coated second nanostructures 54. The dashed line between the first work function metal layer 102A and the surface oxide layer 103 in FIG. 16D represents that this is a gradient oxidation and distinct boundaries may not be present between the layers at this point.

Due to the stacking and proximity of second nanostructures 54 (according to the embodiment shown in FIGS. 14A through 21C where the first nanostructures 52 were the nanostructures removed), the oxidation process may be controlled to preferentially oxidize the first work function metal layer 102A on the outside portions of the stack of second nanostructures 54 (i.e., the top and sides of the stack of second nanostructure 54), substantially converting the outside portions of the first work function metal layer 102A to a surface oxide layer 103. However, due to the constricted space between second nanostructures 54, and between bottom second nanostructure 54A and the substrate fin 66, the first work function metal layer 102A located in these areas will oxidize at a slower rate, resulting in thicker un-oxidized portions of the first work function metal layer 102A (and progressively thinner surface oxide layer 103 closer to the center of the voids between vertically adjacent second nanostructures 54) in those areas, as schematically shown in FIG. 16D.

For example, as shown in FIG. 16D, where the first work function metal layer 102A is deposited as a titanium nitride (TiN) layer, the oxidation process may be controlled to substantially allow the majority of the surfaces of the first work function metal layer 102A not located in the voids between second nanostructures 54 to oxidize to create a surface oxide layer 103 of titanium oxide (TiO₂). However, substantial amounts of the first work function metal layer 102A located between second nanostructures may remain as, for example, titanium nitride (TiN). In the embodiment shown in FIG. 16C, the conversion of the first work function metal layer 102A to the surface oxide layer 103 may result in a roughly linear shape of the remaining un-oxidized portion of the first work function metal layer 102A in the voids between second nanostructures 54. However, other shapes of the remaining first work function metal layer 102A are contemplated, and may comprise convex or concave shapes at the entrances of the voids between second nanostructure 54, as shown, for example, in FIG. 16D. The gradient oxidation of the first work function metal layer 102A may be chosen among any suitable thermal and plasma treatments. In some embodiments, the oxidation process of the first work function metal layer 102A may use a temperature in the range of 25° C. and 650° C. and pressure in the range of 1-200 torr.

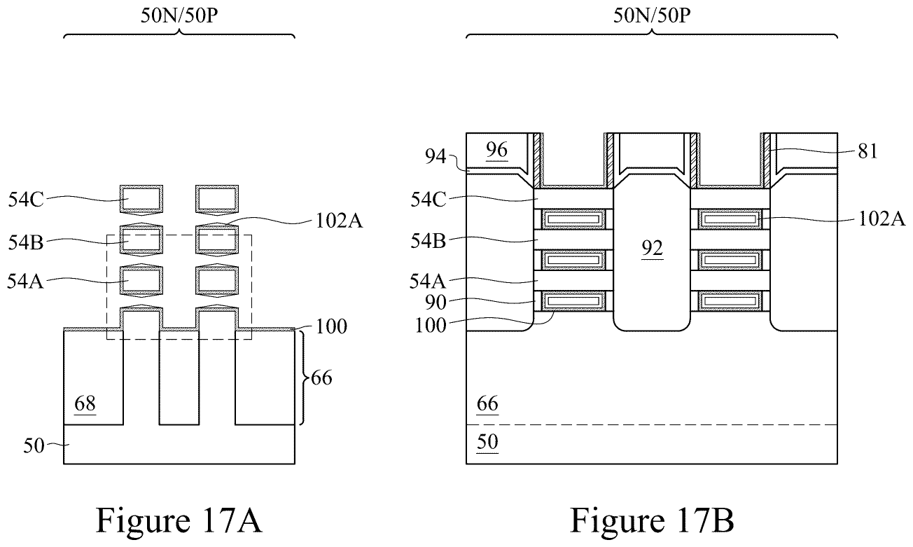

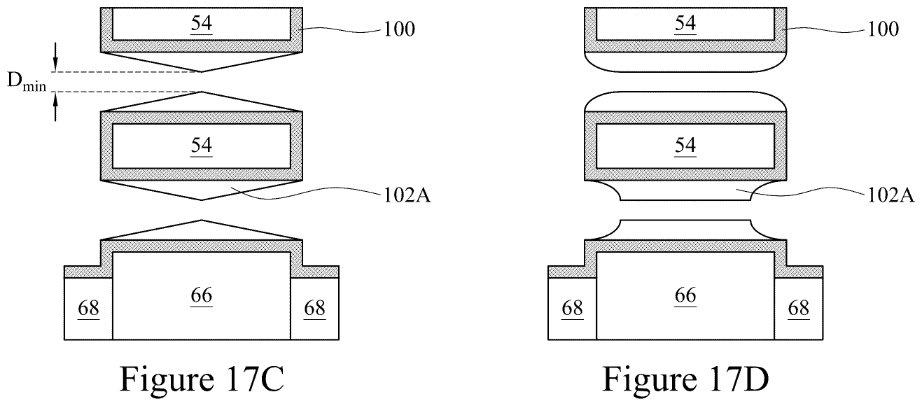

In FIGS. 17A and 17B, the first work function metal layer 102A is subjected to a selective etching process, according to some embodiments. An etch with a high selectivity for the oxidized part of the first work function metal layer 102A (as opposed to the base metal), may be utilized to remove the oxidized portion of the first work function metal layer 102A, resulting in a v-shape sheet-to-sheet opening profile between second nanostructures 54. This is shown more clearly in FIG. 17C, which is an enlarged portion of FIG. 17A bounded by the dashed box. While the embodiment shown in FIG. 17C illustrates a roughly linear slope of the remaining first work function metal layer 102A, other shapes are contemplated also resulting in a gradual narrowing of the void between second nanostructures towards the centerline. For example, the remaining first work function metal layer 102A may have a convex or concave shape at the entrances of the voids between second nanostructure 54, as shown, for example, in FIG. 17D.

In some embodiments, the selective etch may be performed using tungsten chloride (WCl₅), tungsten fluoride (WF₆), or some other metal-halide gas. In some embodiments, the etch may be performed at a temperature range between 200° C. and 600° C. In some embodiments, the first work function metal layer 102A may be completely removed from the outside portions of the stack of second nanostructures 54, and only remain in the areas between adjacent second nanostructures 54, and between the bottom second nanostructure 54A and substrate fin 66.

In some embodiments, an unoxidized layer of the base metal of the first work function metal layer 102A may remain to coat each second nanostructure 54. In such cases where a portion of the first work function metal layer 102A is left around outside portions of the second nanostructure 54 stack after the oxidation and etching process, the unoxidized portion of the first work function metal layer 102A may serve as an etch stop for removal of the surface oxide layer 103 using the selective etching process described above. In some embodiments, the first work function metal layer 102A may be between 0.5 and 3 nm thick in the area between adjacent second nanostructures 54, and may be between 0.0 and 1 nm thick outside the channel portions. In some embodiments, a minimum distance (Dₘᵢₙ, see FIG. 17C) between the first work function metal layer 102A on adjacent second nanostructures 54 may be between 0.0 nm and 9.0 nm. p FIGS. 18A and 18B illustrate the deposition of a second work function metal layer 102B, according to some embodiments. The second work function metal layer 102B is deposited over the first work function metal layer 102A and the gate dielectric layers 100 to completely or partially fill in the gate electrodes 102 (comprising both the first work function metal layer 102A and second work function metal layer 102B structures). In some embodiments, the gate electrodes 102 may further include a fill metal in conjunction with the second work function metal layer 102B. In some embodiments, the second work function metal layer 102B or the fill metal may also deposited over the exposed tops of the first ILD 96, gate spacers 81, and CESL 94, and removed from the tops of those structures through the planarization process described below. The second work function metal layer 102B may include a metal-containing material such as titanium nitride, titanium silicium nitride (TiSiN), titanium aluminum nitride (TiAlN), tungsten carbonitride (WCN), molybdenum nitride (MoN), aluminum-doped titanium carbide (TiAlC), or other work function metals. In some embodiments, the second work function metal layer 102B may have a minimum thickness between 1 nm and 5 nm in the channel areas of the second nanostructure 54 stack. In some embodiments, the second work function metal layer 102B may be selected for specific threshold voltage tuning properties.

For the sake of simplicity, the formation of the gate electrodes 102 in the n-type region 50N and the p-type region 50P have been shown in the previous description and figures to occur simultaneously. However, due to the differences in operation and materials used in n-type and p-type semiconductors, it is expected that different deposition processes will occur in each of the n-type region 50N and p-type region 50N. For instance, the first work function metal layer 102A may formed in both n-type region 50N and p-type region 50N, and the second work function metal layer 102B may only be formed in, for example, the n-type region 50N. In some embodiments, the first work function metal layer 102A and the second work function metal layer 102B may be formed from the same materials across multiple regions and region types (i.e., n-type region 50N and p-type region 50P). However, it is expected that embodiments exist consistent with this disclosure in which the gate electrodes 102 in each region may be formed by distinct processes, such that the gate electrodes 102 may be different materials and/or have a different number of layers in the n-type region 50N compared to the p-type region 50P. Further, the gate electrodes 102 may comprise other layers in addition to the first work function metal layer 102A and second work function metal layer 102B, for example, including a glue layer or layers, a tuning layer or layers deposited prior to the first work function metal layer 102A, fill metals, or the like. Various masking steps may be also be used to mask and expose appropriate regions when using distinct processes, while being fully consistent with the anticipated use of the above disclosure.

By utilizing the deposition, oxidation, etch, and fill technique described above, gap-filled performance of work function metal between sheet-to-sheet layers in a gate all around (GAA) structure is improved, and seems between interfaces become less. Further, high selectivity for the selective etch of the oxidized layer may be achieved, resulting in lower impact to other layers from the oxidation and etch process. Punch-through reduction may also be achieved limiting fin-top damage and helping to maintain full coverage of metal-cap films.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 (comprising at least the first work function metal layer 102A and/or second work function metal layer 102B) and the gate dielectric layers 100 may be collectively referred to as “gate structures. ”

FIGS. 18C and 18D illustrates a detailed view of various elements of FIGS. 18A and 18B (respectively), including the epitaxial source/drain regions 92, the gate dielectric layers 100, the gate electrodes 102 (comprising at least the first work function metal layer 102A and/or second work function metal layer 102B), the second nanostructures 54, and the inner spacers 90. In some embodiments, as illustrated by FIG. 18D, a residue of the sacrificial material segments 72 may remain on the inner spacers 90, such as between the inner spacers 90 and the gate dielectric layers 100/gate electrodes 102. For example, the sacrificial material segments 72 may not be fully removed, and the gate dielectric layers 100 may be formed on the remaining sacrificial material segments 72. Because the sacrificial material segments 72 is an insulating material (e.g., silicon oxide), the remaining residue may not significantly impact the electrical performance of the resulting device.

In FIGS. 19A-19C, the gate structure (including the gate dielectric layers 100 and the corresponding overlying gate electrodes 102) is recessed, so that a recess is formed directly over the gate structure and between opposing portions of gate spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 21A-21C) penetrate through the gate mask 104 to contact the top surface of the recessed gate electrodes 102.

As further illustrated by FIGS. 19A-19C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

In FIGS. 20A-20C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIG. 20B illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts.

After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., capable of reacting with silicon, silicon germanium, germanium) to form silicide or germanide regions. For example, metals such as nickel, cobalt, titanium, tantalum, platinum, tungsten, other noble metals, other refractory metals, rare earth metals or their alloys, may be used. The metal may be deposited over the exposed portions of the epitaxial source/drain regions 92. A thermal annealing process may then be utilized to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

Next, in FIGS. 21A-21C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and are electrically coupled to the underlying conductive feature (e.g., gate electrode 102 and/or silicide region 110 in the illustrated embodiment). The contacts 114 are electrically coupled to the gate electrode 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

By utilizing the techniques described above, gap-filled performance of work function metal between sheet-to-sheet layers in a gate all around (GAA) structure is improved, and seems between interfaces become less. Further, high selectivity for the selective etch of the oxidized layer may be achieved, resulting in lower impact to other layers from the oxidation and etch process. Punch-through reduction may also be achieved limiting fin-top damage and helping to maintain full coverage of metal-cap films. Accordingly, smaller and thinner features may be realized resulting in increased miniaturization, increased efficiency, reduced power consumption, and reduced power losses and heat generation.

In a first embodiment, a method is provided including: forming a multi-layer stack over a substrate, the multi-layer stack including alternating layers of first semiconductor material and second semiconductor material; patterning the multi-layer stack into a fin including and alternating first nanostructures of the first semiconductor material and at least two second nanostructures of the second semiconductor material in a first region of the substrate; removing the first nanostructures in the first region of the substrate from the multi-layer stack; forming a first work function metal layer around each of the at least two second nanostructures; oxidizing a portion of the first work function metal layer, where an un-oxidized portion remains in an area between the at least two second nanostructures; removing the oxidized portion of the first work function metal layer; and forming a second work function metal layer around each of the at least two second nanostructures, where the second work function metal layer and the first work function metal layer fill a space between the at least two second nanostructures.

In some embodiments, the method further includes, before forming the first work function metal layer, and after removing the first nanostructures: forming a sacrificial material between the second semiconductor layers in the first region; forming source/drain regions adjacent the at least two second nanostructures and the sacrificial material in the first region; and removing the sacrificial material between from between the at least two second nanostructures. In some embodiments, the sacrificial material is selected from the group consisting of silicon oxide, silicon oxynitride, and aluminum oxide. In some embodiments, the method further includes forming inner spacers on sidewalls of the sacrificial material before forming the source/drain regions, where the inner spacers have a dielectric constant less than 3.5. In some embodiments, the inner spacers include silicon nitride, silicon oxynitride, or a combination thereof. In some embodiments, oxidizing the portion of the first work function metal layer includes performing a thermal oxidation in a range from 25° C. to 650° C. In some embodiments, removing the oxidized portion of the first work function metal layer includes performing a selective etch in a range from 25° C. to 650° C. using a gas including a metal-halide gas. In some embodiments, before oxidizing the portion of the first work function metal layer, the first work function metal layer is between 1 nanometers (nm) and 3.5 nm. In some embodiments, after removing the oxidized portion of the first work function metal layer, the first work function metal layer is between 1 nm and 3.5 nm thick in an area between the at least two second nanostructures, the first work function metal layer is thinner towards an outside of the area between the at least two second nanostructures, and the first work function metal layer is thicker towards the center of the area between the at least two second nanostructures forming a v-shaped profile between the at least two second nanostructures.

In a second embodiment a method is providing, the method including: forming a first work function metal layer around a first nanostructure in a fin disposed over a substrate; oxidizing at least a portion of the first work function metal layer, where less of the work function metal layer is oxidized between the first nanostructure and an adjacent second nanostructure in a stack in the fin; removing oxidized portions of the first work function metal layer from around the first nanostructure; and forming a second work function metal layer around the first nanostructure, where the first work function metal layer and the second work function metal layer fill a void between the first nanostructure and the adjacent second nanostructure.

In some embodiments, the first work function metal layer is between 1 nanometers (nm) and 3.5 nm prior to being oxidized, and the first work function metal layer does not completely fill the void between the first nanostructure and the adjacent second nanostructure. In some embodiments, after removing oxidized portions of the first work function metal layer, the first work function metal layer on the first nanostructure is between 0.5 nm and 3 nm thick in the void between the first nanostructure and the adjacent second nanostructure, the first work function metal layer is thinner towards sidewalls of the fin, and the first work function metal layer is thicker towards a centerline of the fin forming a v-shaped profile at opposite entrances of the void between the first nanostructure and the adjacent second nanostructure. In some embodiments, the first work function metal layer includes at last one of titanium nitride, titanium silicium nitride, titanium aluminum nitride, tungsten carbonitride, molybdenum nitride, and aluminum-doped titanium carbide, and oxidizing at least the portion of the first work function metal layer includes performing a thermal oxidation in a range from 25° C. to 650° C. In some embodiments, removing oxidized portions of the first work function metal layer from around the first nanostructure includes performing a selective etch using a metal-halide gas in a range from 200° C. to 600° C. In some embodiments, the method further includes, before forming the first work function metal layer around the first nanostructure: removing a disposable oxide interposer from between the first nanostructure and the adjacent second nanostructure to form the void between the first nanostructure and the adjacent second nanostructure; and forming a gate dielectric layer around the first nanostructure and the adjacent second nanostructure. In some embodiments, the gate dielectric is between 2 nm and 10 nm thick. In some embodiments, the disposable oxide interposer is formed from a material selected from the group consisting of silicon oxide, silicon oxynitride, and aluminum oxide.

In a third embodiment a semiconductor device is provided, the device including: a first nanostructure and a second nanostructure in a stack over a substrate fin; a gate dielectric layer surrounding the first nanostructure and the second nanostructure; a first work function metal layer filling a portion of a space between, and disposed on each of, the first nanostructure and the second nanostructure; a second work function metal layer filling at least a portion of the remainder of the space between the first nanostructure and the second nanostructure not filled by the first work function metal layer; an epitaxial source/drain region on adjacent sides of the stack; and a gate electrode including the first work function metal layer, and the second work function metal layer.

In some embodiments of the semiconductor device, the first work function metal layer forms a v-shaped entrance to the space between the first nanostructure and the second nanostructure, where a distance between the first work function metal layer on the first nanostructure and the first work function metal layer on the second nanostructure is wider closer to sidewalls of the stack and narrows to a minimum distance towards a centerline of the stack. In some embodiments of the semiconductor device, the first work function metal layer includes a material selected from the group consisting of titanium nitride, titanium silicium nitride, titanium aluminum nitride, tungsten carbonitride, molybdenum nitride, and aluminum-doped titanium carbide.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a multi-layer stack over a substrate, the multi-layer stack comprising alternating layers of first semiconductor material and second semiconductor material;
patterning the multi-layer stack into a fin comprising and alternating first nanostructures of the first semiconductor material and at least two second nanostructures of the second semiconductor material in a first region of the substrate;
removing the first nanostructures in the first region of the substrate from the multi-layer stack;
forming a first work function metal layer around each of the at least two second nanostructures;
oxidizing a portion of the first work function metal layer, wherein an un-oxidized portion remains in an area between the at least two second nanostructures;
removing the oxidized portion of the first work function metal layer; and
forming a second work function metal layer around each of the at least two second nanostructures, wherein the second work function metal layer and the first work function metal layer fill a space between the at least two second nanostructures.

2. The method of claim 1, wherein the method further comprises, before forming the first work function metal layer, and after removing the first nanostructures:
forming a sacrificial material between the second semiconductor layers in the first region;
forming source/drain regions adjacent the at least two second nanostructures and the sacrificial material in the first region; and
removing the sacrificial material between from between the at least two second nanostructures.

3. The method of claim 2, wherein the sacrificial material is selected from the group consisting of silicon oxide, silicon oxynitride, and aluminum oxide.

4. The method of claim 2, further comprising:
forming inner spacers on sidewalls of the sacrificial material before forming the source/drain regions, wherein the inner spacers have a dielectric constant less than 3.5.

5. The method of claim 4, wherein the inner spacers comprise silicon nitride, silicon oxynitride, or a combination thereof.

6. The method of claim 1, wherein oxidizing the portion of the first work function metal layer comprises:
performing a thermal oxidation in a range from 25° C. to 650° C.

7. The method of claim 6, wherein removing the oxidized portion of the first work function metal layer comprises:
performing a selective etch in a range from 25° C. to 650° C. using a gas comprising a metal-halide gas.

8. The method of claim 1, wherein, before oxidizing the portion of the first work function metal layer, the first work function metal layer is between 1.0 nanometers (nm) and 3.5 nm.

9. The method of claim 1, wherein after removing the oxidized portion of the first work function metal layer, the first work function metal layer is between 0.5 nm and 3.0 nm thick in an area between the at least two second nanostructures, the first work function metal layer is thinner towards an outside of the area between the at least two second nanostructures, and the first work function metal layer is thicker towards the center of the area between the at least two second nanostructures forming a v-shaped profile between the at least two second nanostructures.

10. A method, comprising:
forming a first work function metal layer around a first nanostructure in a fin disposed over a substrate;
oxidizing at least a portion of the first work function metal layer, wherein less of the work function metal layer is oxidized between the first nanostructure and an adjacent second nanostructure in a stack in the fin;
removing oxidized portions of the first work function metal layer from around the first nanostructure; and
forming a second work function metal layer around the first nanostructure, wherein the first work function metal layer and the second work function metal layer fill a void between the first nanostructure and the adjacent second nanostructure.

11. The method of claim 10, wherein the first work function metal layer is between 1.0 nanometers (nm) and 3.5 nm prior to being oxidized, and the first work function metal layer does not completely fill the void between the first nanostructure and the adjacent second nanostructure.

12. The method of claim 10, wherein after removing oxidized portions of the first work function metal layer, the first work function metal layer on the first nanostructure is between 0.5 nm and 3.0 nm thick in the void between the first nanostructure and the adjacent second nanostructure, the first work function metal layer is thinner towards sidewalls of the fin, and the first work function metal layer is thicker towards a centerline of the fin forming a v-shaped profile at opposite entrances of the void between the first nanostructure and the adjacent second nanostructure.

13. The method of claim 10, wherein:
the first work function metal layer comprises at last one of titanium nitride, titanium silicium nitride, titanium aluminum nitride, tungsten carbonitride, molybdenum nitride, and aluminum-doped titanium carbide, and
oxidizing at least the portion of the first work function metal layer comprises performing a thermal oxidation in a range from 25° C. to 650° C.

14. The method of claim 10, wherein removing oxidized portions of the first work function metal layer from around the first nanostructure comprises:
performing a selective etch using a metal-halide gas in a range from 200° C. to 600° C.

15. The method of claim 10, further comprising, before forming the first work function metal layer around the first nanostructure:
removing a disposable oxide interposer from between the first nanostructure and the adjacent second nanostructure to form the void between the first nanostructure and the adjacent second nanostructure; and
forming a gate dielectric layer around the first nanostructure and the adjacent second nanostructure.

16. The method of claim 15, wherein the gate dielectric is between 2.0 nm and 10.0 nm thick.

17. The method of claim 15, wherein the disposable oxide interposer is formed from a material selected from the group consisting of silicon oxide, silicon oxynitride, and aluminum oxide.

18. A semiconductor device, comprising:
a first nanostructure and a second nanostructure in a stack over a substrate fin;
a gate dielectric layer surrounding the first nanostructure and the second nanostructure;
a first work function metal layer filling a portion of a space between, and disposed on each of, the first nanostructure and the second nanostructure;
a second work function metal layer filling at least a portion of the remainder of the space between the first nanostructure and the second nanostructure not filled by the first work function metal layer; and
an epitaxial source/drain region on adjacent sides of the stack; and
a gate electrode comprising the first work function metal layer, and the second work function metal layer.

19. The semiconductor device of claim 18, wherein the first work function metal layer forms a v-shaped entrance to the space between the first nanostructure and the second nanostructure, wherein a distance between the first work function metal layer on the first nanostructure and the first work function metal layer on the second nanostructure is wider closer to sidewalls of the stack and narrows to a minimum distance towards a centerline of the stack.

20. The semiconductor device of claim 18, wherein the first work function metal layer comprises a material selected from the group consisting of titanium nitride, titanium silicium nitride, titanium aluminum nitride, tungsten carbonitride, molybdenum nitride, and aluminum-doped titanium carbide.
